(19) United States
(12) Patent Application Publication
(10) Pub. No.: US 2003/0116426 A1
(43) Pub. Date: Jun. 26, 2003

(54) Method of depositing heusler alloy thin film by co-sputtering

(76) Inventors: Kee-won Kim, Yongin-city (KR); Wan-Jun Park, Seoul (KR); Tae-wan Kim, Anyang-city (KR); I-hun Song, Seongnam-city (KR); Sang-jin Park, Pyeongtaek-city (KR)

Correspondence Address: LEE & STERBA, P.C., 1101 WILSON BOULEVARD, SUITE 2000, ARLINGTON, VA, 22209, US

(21) Appl. No.: 10/309,212

(22) Filed: Dec. 4, 2002

(30) Foreign Application Priority Data
Dec. 7, 2001 (KR) 2001-77421

(51) Int. Cl. C23C 14/32

(52) U.S. Cl. 204/192.15; 204/192.2

(57) ABSTRACT

A method of manufacturing a Heusler alloy thin film by co-sputtering is provided. The Heusler alloy thin film has a general structural formula of either X₂YZ or XYZ and is deposited by co-sputtering using a deposition apparatus having a substrate placed on a substrate holder in a chamber and targets positioned on a target bracket spaced apart from the substrate. Components of the Heusler alloy thin film are placed on the target bracket as either single targets or binary alloy targets. Thus, it is easy to manufacture a Heusler alloy thin film having excellent magnetic characteristics.

### BACKGROUND OF THE INVENTION

1. Field of the Invention

The present invention relates to a method of depositing a Heusler alloy thin film. More particularly, the present invention relates to a method of forming a Heusler alloy thin film having an improved property by depositing materials constituting the Heusler alloy thin film by co-sputtering at the same time.

2. Description of the Related Art

A magnetic random access memory (MRAM) is a nonvolatile solid magnetic memory device. An MRAM uses a giant magnetoresistance effect based on a particular spin dependence conduction phenomenon of a nano magnet. The giant magnetoresistance phenomenon occurs because electron spin (degree of freedom of an electron), has a great effect on an electron transmission, or a tunnel magnetoresistance phenomenon.

Giant magnetoresistance (GMR) refers to a phenomenon in which differences in resistance occur when the spin between ferromagnetic substances in an arrangement of ferromagnetic substance/metal nonmagnetic substance/ferromagnetic substance is equally and oppositely arranged. Tunnel magnetoresitance (TMR) refers to a phenomenon in which transmission of current is easier when the spin is equally arranged on two ferromagnetic layers in an arrangement of ferromagnetic substance/insulator/ferromagnetic substance than when the spin is oppositely arranged.

In the case of the MRAM using the GMR phenomenon, the difference in resistance values due to magnetization directions is relatively small and thus the difference in voltage values cannot be great. Also, a MOSFET combined with a GMR layer to constitute a cell has to be large. Thus, studies have focused more on practical use of the MRAM using a TMR layer than using a GMR layer.

It is very important to realize a magnetoresistant device having a high magnetoresistance (MR) rate in an MRAM. It is generally known that MR rate is directly related to spin polarization of a magnetic thin film. It is known that about 60% MR rate of CoFe is currently the greatest value. In the 1980s, 100% spin polarization in which the spin of electrons contributing to conduction in a Heusler alloy exists only in one direction had theoretically been foreseen and proven in a test. Many attempts have been made to reproduce this characteristic in spintronics devices, but making Heusler alloy into a thin film is very difficult.

In general, Heusler alloy is deposited by sputtering, using molecular beam epitaxy (MBE) or in a state that a chip is placed on a target. However, this conventional method of manufacturing a Huesler alloy thin film is inefficient because of a productivity problem and a composition control problem. The efficiency of sputtering is widely accepted when depositing a general alloy thin film. However, Heusler alloy has a fragile characteristic and thus it is difficult to manufacture Heusler alloy as targets.

### SUMMARY OF THE INVENTION

To solve the problems described above, it is a feature of an embodiment of the present invention to provide a method of efficiently manufacturing a Heusler alloy thin film which is applicable to a TMR cell structure of an MRAM.

Accordingly, to provide the feature described above, there is provided a method of manufacturing a Heusler alloy thin film having a general structural formula of X₂YZ or XYZ deposited by co-sputtering using a deposition apparatus having a substrate placed on a substrate holder in a chamber and targets positioned on a target bracket spaced apart from the substrate. Here, components of the Heusler alloy thin film are placed on the target bracket as either single targets or binary alloy targets.

The substrate holder is preferably maintained at a temperature of about 200-500° C. The chamber is preferably maintained in a vacuum of 10⁻²-10⁻³ Torr. The distance between the substrate and the targets is preferably within a range of about 5-20 cm.

### BRIEF DESCRIPTION OF THE DRAWINGS

The above features and advantages of the present invention will become more apparent by describing in detail preferred embodiments thereof with reference to the attached drawings in which:

FIGS. 1A and 1B illustrate a schematic cross-sectional view and a plan view of a sputtering system used in depositing a Heusler alloy thin film according to the present invention;

FIGS. 2A through 2D illustrate graphs of magnetic characteristics measured with VSM with respect to a Heusler alloy thin film manufactured by changing a temperature of a substrate according to the present invention;

FIGS. 3A and 3B illustrate graphs of magnetic characteristics measured on the basis of substrate temperatures with respect to a Heusler alloy thin film manufactured by changing a temperature of a substrate according to the present invention; and

FIG. 4 illustrates a graph showing X-ray diffraction measured with respect to a Heusler alloy thin film manufactured by changing a temperature of a substrate according to the present invention.

### DETAILED DESCRIPTION OF THE INVENTION

In a method of manufacturing a Heusler alloy thin film by co-sputtering according to the present invention, each of components constituting the Heusler alloy thin film is sputtered as a single target.

A general structural formula of Heusler alloy is X₂YZ. Preferably, X is one of Co, Cu, Ni or Fe-based metals, Y is Mn or Ti, and Z is a nonmagnetic material of either a 3A group or a 4A group, and is one of Al, Si, Ga, Ge, Sn, and Sb. Also, the structural formula of XYZ of the Heusler alloy thin film is preferably one of PtMnSb or NiMnSb.

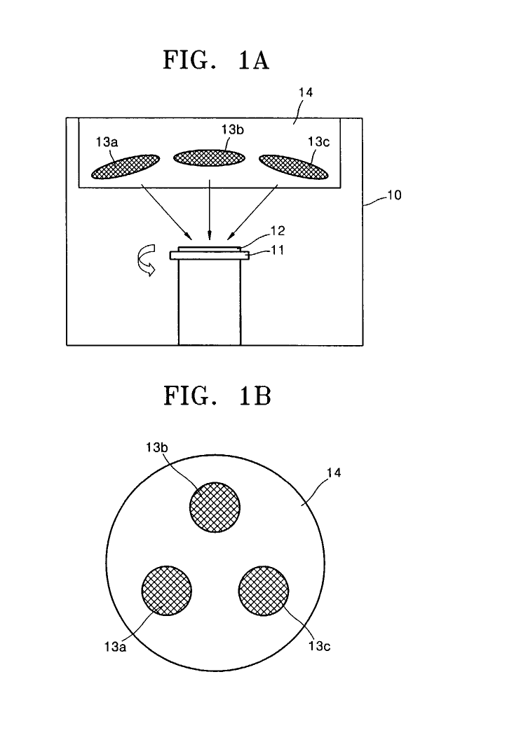

A method of manufacturing a Heusler alloy thin film will be described with reference to FIGS. 1A and 1B. FIG. 1A illustrates a schematic cross-sectional view of a sputtering system used in a process of manufacturing a Heusler alloy thin film by co-sputtering according to the present invention. FIG. 1 B illustrates a plan view of each single target placed on a target bracket, each single target being a component of a Heusler alloy thin film. Components constituting a Heusler alloy thin film, e.g., Cu, Mn, Al targets 13a, 13b, and 13c, are placed on a target bracket 14 in a chamber 10 of a sputtering system. A CuMnAl alloy is deposited on a substrate 11 after deposition conditions are set based on the components.

Here, the CuMnAl alloy may be formed of one of binary alloys such as CuMn, CuAl, or MnAl and one of Cu, Mn, and Al.

To deposit the components of the Heusler alloy thin film, a general sputtering apparatus and a discharging gas may be used while controlling a deposition rate.

A method of manufacturing a Heusler alloy thin film according to an embodiment of the present invention will now be described in more detail.

First, single targets 13a, 13b, and 13c constituting a Heusler alloy thin film are deposited on a target bracket 14. A substrate 12 is placed on a substrate holder 11. Here, the inside of a chamber 10 of the sputtering system is maintained at a predetermined vacuum, which is generally about 7×10⁻¹⁰ Torr. A discharging gas, e.g., Ar, is supplied into the chamber 10. Here, the vacuum is within a range of 10⁻³-10⁻² Torr. A vacuum pump and a discharging gas supply apparatus operate to maintain the vacuum. The substrate 12 is maintained at a temperature of about 200-500° C., and the substrate holder 11 rotates at a predetermined speed. Here, the distance between the substrate 12 and the targets 13a, 13b, and 13c may depend on types of sputtering systems used, and is generally within a range of about 5-20 cm. This process is the same as a general sputtering process.

A voltage is applied between the substrate holder 11 and the target bracket 14 to make the discharging gas into plasma. As a result, components constituting the Heusler alloy thin film are deposited on the substrate 12. Here, a deposition rate of Cu is about 83 Å/min, a deposition rate of Mn is about 44 Å/min, and a deposition rate of Al is about 57 Å/min. In the method of manufacturing a Heusler alloy thin film according to the present invention, a Heusler alloy thin film having excellent characteristics may be formed if deposition rates of components of the Heusler alloy thin film are kept low. This may depend on the types of sputtering systems used.

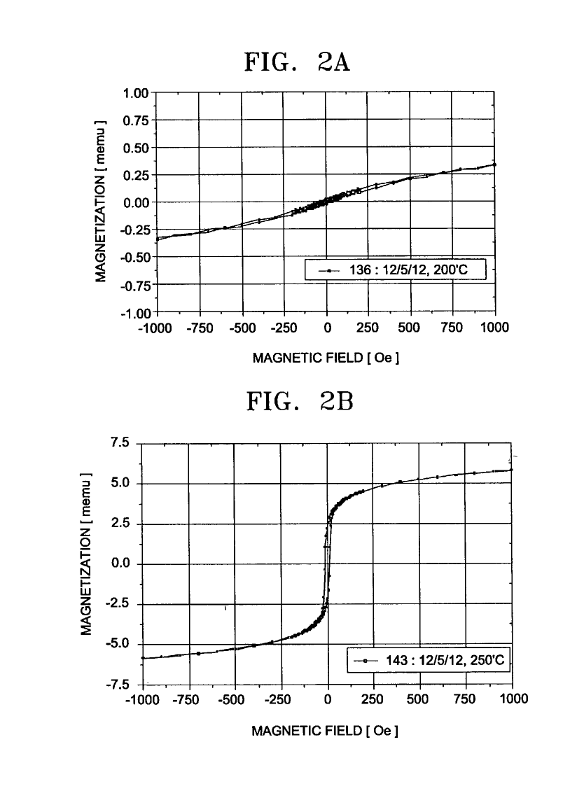

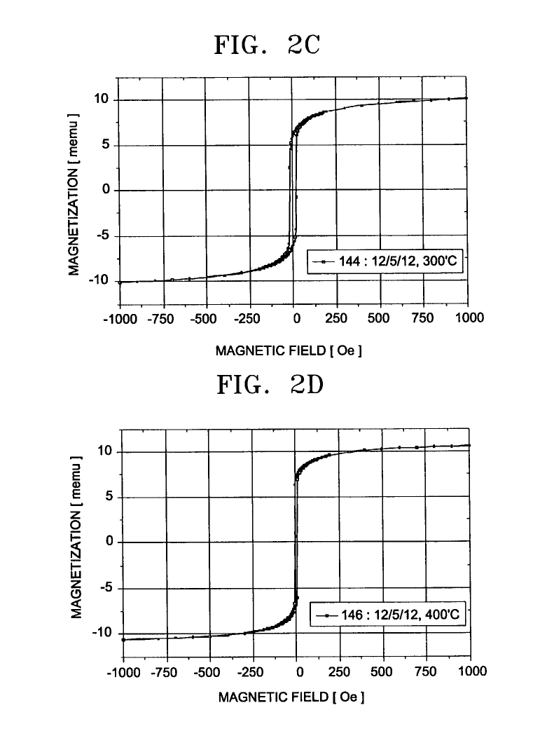

FIGS. 2A through 2D illustrate graphs showing magnetic characteristics of a Heusler alloy thin film manufactured by co-sputtering based on changes in temperature of a substrate, which are measured using a VSM apparatus, according to the present invention.

In FIG. 2A, a Heusler thin film is deposited on a substrate having a temperature of about 200° C. for about 20 minutes. Here, it is apparent that the Heusler alloy thin film does not have magnetic characteristics suitable for use in an MRAM. In FIG. 2B, a Heusler alloy thin film is deposited on a substrate having a temperature of about 250° C. for about 20 minutes. Here, it is apparent that the Heusler alloy thin film has distinct magnetic characteristics and a considerably increased magnetization value compared to the Heusler alloy thin film deposited at the temperature of about 200° C. shown in FIG. 2A. In FIG. 2C, a Heusler alloy thin film is deposited on a substrate having a temperature of about 300° C. for about 20 minutes. It is apparent form FIG. 2C that the Heusler alloy thin film deposited on the substrate having a temperature of about 300° C. has a greater magnetization value than the Heusler alloy thin film deposited on a substrate having a temperature of about 250° C. shown in FIG. 2B. In FIG. 2D, a Heusler alloy thin film is deposited on a substrate having a temperature of about 400° C. for about 20 minutes. It is apparent from FIG. 2D that the Heusler alloy thin film deposited on a substrate having a temperature of about 400° C. has the highest saturation magnetization value.

The distance between the substrate and targets in the deposition of the Heusler alloy thin films of FIGS. 2A-2D is about 10 cm. During deposition of each Heusler alloy thin film as depicted in FIGS. 2A-2D, only the temperature of the substrate is varied, while all other conditions remain constant. Thus, the Heusler alloy thin films deposited on the substrates are the same, and only the temperatures of the substrates are different.

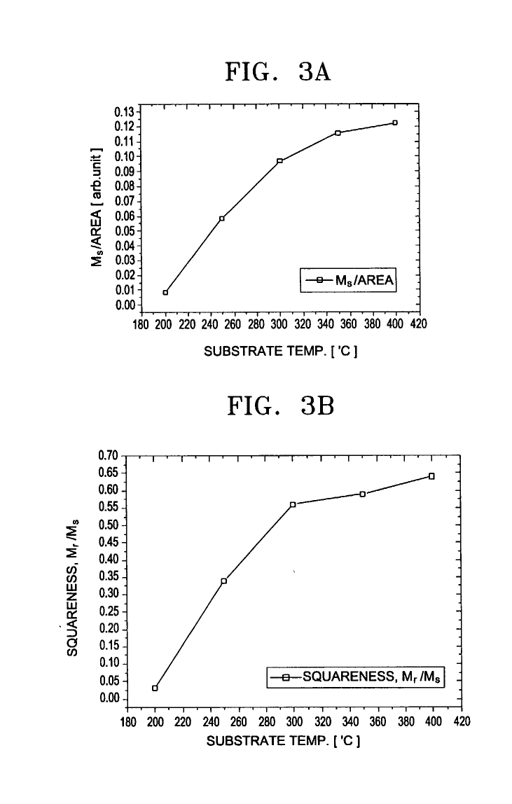

FIGS. 3A and 3B illustrate graphs showing Mₛ/Area values and Mᵣ/Mₛ values of a Heusler alloy thin film based on a temperature of a substrate according to the present invention. Here, Mₛ values represent saturation magnetization values, Mᵣ values represent remaining magnetization values, and Area represents the area of a substrate.

Referring to FIGS. 3A and 3B, it is apparent that magnetization characteristics of the Heusler alloy thin film improve with an increase in the substrate temperature. The magnetization characteristics of a Heusler alloy thin film deposited on a substrate having a temperature of about 250° C. are greatly improved over those of a Heusler alloy thin film deposited on a substrate having a temperature of about 200° C. However, the rate of improvement of the magnetization characteristics of the Heusler alloy thin film decreases with an increase in the temperature of the substrate. For example, when the temperature of the substrate is increased from 200° C. to 250° C., the amount of improvement in the magnetization characteristics is greater than the amount of improvement in the magnetization characteristics when the temperature of the substrate is increased from 300° C. to 350° C.

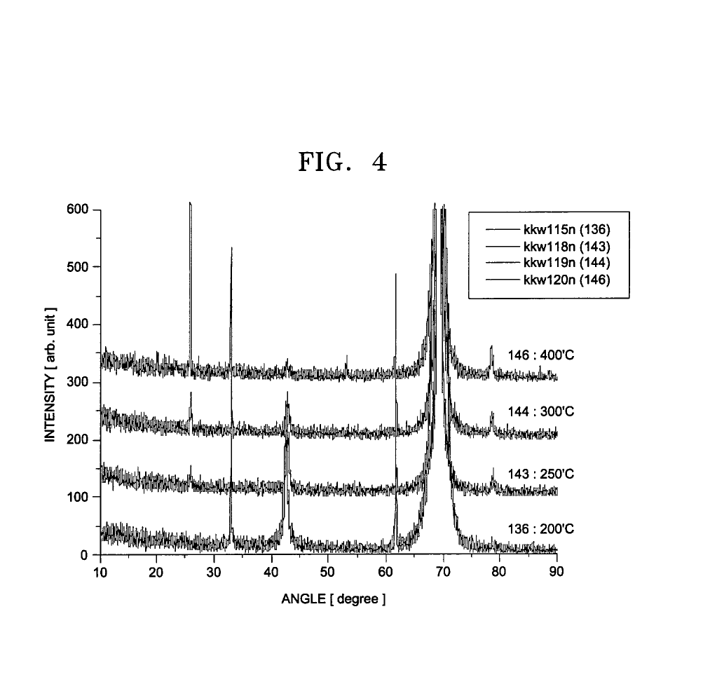

FIG. 4 illustrates a graph showing X-ray diffraction measured with respect to a Heusler alloy thin film manufactured by changing a substrate temperature according to the present invention. Characteristics of a Hesuler alloy thin film based on a process temperature will be described in more detail with reference to FIG. 4. In FIG. 4, peaks occurring close to 33°, 62°, and 68° represent characteristic peaks of a silicon substrate. A peak occurring close to 26° represents a superlattice peak. A peak occurring close to 42° represents a peak that indicates that components in a crystal structure of the Heusler alloy are disordered. Here, intensity values when a substrate temperature is 250, 300, and 400° C., respectively, are transferred by a unit of 100 in a y-axis direction for easy comparison. In other words, intensity values in a base section except for characteristic peaks are almost the same. In general, if a superlattice peak occurs, it is known that the Heusler alloy thin film has excellent characteristics as a magnetic thin film. Here, the supperlattice peak at around 26° increases as the temperature of the substrate increases and the peak at around 42°, which indicates disorder of the crystal structure of the Heusler thin film, decreases as the temperature of the substrate increases.

The method according to an embodiment of the present invention allows easy manufacture of a Heusler alloy thin film having excellent magnetic characteristics. A co-sputtering deposition method may be easily varied depending on changes in components constituting the Heusler alloy thin film and composition. The Heusler alloy thin film provided by the present invention may be easily adopted in the manufacture of an MRAM due to improved characteristics such as a high MR rate. As a result, an MRAM having excellent efficiency may be provided. Uniformity tolerance, reliability, and yield may be improved in the manufacture of the MRAM using the method of the present invention. Also, if the Heusler alloy thin film is adopted in a magnetoresistant memory device of the MRAM, a signal-to-noise (S/N) ratio and sensing margin may increase, and reduction in the MR rate due to the dependence of the MR rate on a bias voltage may decrease.

Preferred embodiments of the present invention have been disclosed herein and, although specific terms are employed, they are used in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of manufacturing a Heusler alloy thin film having a structural formulas of either X₂YZ or XYZ deposited by co-sputtering using a deposition apparatus having a substrate placed on a substrate holder in a chamber and targets positioned on a target bracket spaced apart from the substrate,
wherein components of the Heusler alloy thin film are placed on the target bracket as either single targets or binary alloy targets.

2. The method as claimed in claim 1, wherein the substrate holder is maintained at a temperature of about 200-500° C.

3. The method as claimed in claim 1, wherein the chamber is maintained in a vacuum of 10⁻²-10⁻³ Torr.

4. The method as claimed in claim 1, wherein the distance between the substrate and the targets is within a range of about 5-20 cm.

5. The method as claimed in claim 1, wherein in the structural formula X₂YZ of the Heusler alloy thin film, X is one of Co, Cu, Ni or Fe-based metals, Y is Mn or Ti, and Z is a nonmagnetic material of either a 3A group or a 4A group, and is one of Al, Si, Ga, Ge, Sn, and Sb.

6. The method as claimed in claim 1, wherein in the structural formula XYZ of the Heusler alloy thin film is one of PtMnSb and NiMnSb.

7. The method as claimed in claim 1, wherein the components of the Heusler alloy thin film are deposited using a general sputtering apparatus and a discharging gas, while a rate of deposition is controlled.

8. The method as claimed in claim 7, wherein a voltage is applied between the substrate holder and the target bracket to make the discharging gas into plasma, resulting in the components constituting the Heusler alloy thin film being deposited on the substrate.

9. The method as claimed in claim 7, wherein:
when X is Cu, X is deposited at a rate of about 83 Å/min;
when Y is Mn, Y is deposited at a rate of about 44 Å/min; and
when Z is Al, Z is deposited at a rate of about 57 Å/min.
